(19) United States
(12) Patent Application Publication
(10) Pub. No.: US 2002/0162060 A1
(43) Pub. Date: Oct. 31, 2002

(54) Integrated circuit facilitating its unit test

(76) Inventors: Makoto Hatakenaka, Tokyo (JP); Atsuo Mangyo, Tokyo (JP); Manabu Miura, Tokyo (JP)

Correspondence Address: BURNS DOANE SWECKER & MATHIS L L P, POST OFFICE BOX 1404, ALEXANDRIA, VA, 22313-1404, US

(21) Appl. No.: 09/760,799

(22) Filed: Jan. 17, 2001

(30) Foreign Application Priority Data
Aug. 3, 2000 (JP) 2000-235955

(51) Int. Cl. G11C 29/00

(52) U.S. Cl. 714/718

(57) ABSTRACT

An integrated circuit is provided that can achieve the unit test of its memory simply and positively. It makes a decision as to whether a memory is normal or not according to a 1-bit identity decision result output from an identity/nonidentity decision circuit. It obviates the need for assigning a plurality of decision terminals to each chip to be tested, making it possible to simultaneously test the same number of chips as the total number of the decision terminals of a tester, which is physically limited. It can improve test efficiency and reduce test cost.

### BACKGROUND OF THE INVENTION

1. Field of the Invention

The present invention relates to an integrated circuit capable of achieving a unit test of a memory integrated into a chip together with a logic circuit-simply and positively.

2. Description of Related Art

FIG 5 is a block diagram showing a major portion of a conventional integrated circuit. The conventional integrated circuit 10 comprises a memory along with a wide data bus and its test circuit. In this figure, the reference numeral 201 designates D flip-flops that simultaneously load m-bit (8-bit, in this example) test data supplied to test data input terminals 102 in response to a single clock pulse input to a test data write clock input terminal 103, and immediately output the m-bit test data. The D flip-flops 201 have an output control function for carrying out output control in response to a control signal supplied to an OE terminal from a test output enabling terminal 108.

The reference numeral 202 designates a 16M-bit DRAM (Dynamic Random Access Memory) to be tested. The DRAM 202 acquires address (row address and column address) data supplied to test address input terminals 104 in response to control signals input to a test row address strobe input terminal 105 and a test column address strobe input terminal 106, and loads the test data from the D flip-flops 201 into the address in response to a control signal from the test write enabling terminal 107. As the D flip-flops 201, the DRAM 202 has an output control function for carrying out output control in response to a control signal (an inverted signal of the control signal supplied to the D flip-flops 201) supplied from the test output enabling terminal 108 to its OE negation input terminal.

The reference numeral 203 designates a multiplexer for selecting one of a plurality of input data in response to a selection control signal supplied from test data output selection terminals 109, and for outputting the selected data from test data output terminals 101. The reference numeral 204 designates an identity/nonidentity decision circuit for making an identity/nonidentity decision of each of n sets of m-bit test data. Here, it makes an identity/nonidentity decision of each of the 16 sets of the same 8-bit test data, and supplies the decision result to a test identity/nonidentity decision result output terminal 110. The reference numeral 206 designates an m×n-bit wide data bus for connecting the D flip-flops 201 with the DRAM 202 and multiplexer 203, where m is a test data bus bit width of the chip, and n is the total number of the data buses put together into the wide data bus 206. In this example, the wide data bus 206 has an 8×16 (=128) bit width.

The reference numeral 207 designates m-bit data lines for connecting the D flip-flops 201 with the wide data bus 206. The data lines 207 deliver the same m-bit data to the m×n bit wide data bus 206 as the n sets of m-bit test data. In other words, the data lines 207 in the present example expand the 8-bit data into 16 pieces of the same data and distribute them. The reference numeral 208 designates m-bit data lines for connecting the wide data bus 206 to the identity/nonidentity decision circuit 204. The data lines 208 divide the m×n bit data supplied from the wide data bus 206 to the same n sets of m-bit test data, and delivers them to the identity/nonidentity decision circuit 204. Thus, the 128-bit data are divided into the 16 sets of the same 8-bit test data to be delivered.

Incidentally, a numeral (1, 4, 8, 12 or 128) assigned to a line along with a slash denotes the bit number of the data to be transferred through the line. As for the terminals such as D(7:0) and Q(7:0) of the D flip-flops-201, and A(11:0) and DQ(127:0) of the DRAM 202, the number of bits to be input to or output from the terminals can be seen from these numbers. For example, the terminals D(7:0) are supplied with 8-bit data.

Next, the operation of the conventional integrated circuit 10 will be described.

(1) First, the test data write operation to the DRAM 202 will be described. The 8-bit test data supplied from the test data input terminals 102 is written into the D flip-flops 201 in response to the rising edge of the clock pulse fed from the test data write clock input terminal 103. The 8-bit test data is immediately output from the output terminals Q(7:0) of the D flip-flops 201.

The D flip-flops 201 and DRAM 202 both have the output control function so that when the control signal supplied to the test output enabling terminal 108 is at H level (1), the output terminals Q(7:0) of the D flip-flops 201 are set at an output enabled state, whereas the output terminals DQ (127:0) of the DRAM 202 are set at an output disabled state in which it cannot output data because of the H level (1) supplied to its enabling terminal. In contrast, when the control signal input to the test output enabling terminal 108 is at L level (0), the terminals Q(7:0) of the D flip-flops 201 are set at the output disabled state in which they cannot output the 8-bit test data, whereas the terminals DQ(127:0) of the DRAM 202 are set at the output enabled state in which it can output the data because of the L level (0) control signal input to its enabling terminal. Thus, the D flip-flops 201 and the DRAM 202 can avoid the collision of the output data on the wide data bus 206 thanks to their output control functions. In the test data write operation, the control signal input to the test output enabling terminal 108 is placed at H level (1).

The 8-bit test data output from the output terminals Q(7:0) of the D flip-flops 201 are distributed to the data lines 207 as 16 sets of the same 8-bit test data. Accordingly, the 16 sets of the same 8-bit test data, that is, 128-bit data, are written into the DRAM 202 through the 128-bit wide data bus 206 in a single write operation. The DRAM 202 receives the L level (0) control signal from the test write enabling terminal 107 in the write operation, whereas it receives the H level (1) control signal from the test write enabling terminal 107 in the read operation to undergo read/write control. Thus, when the DRAM 202 loads the 128-bit test data, it receives the L level (0) control signal at the test write enabling terminal 107 without exception.

The 128-bit test data is written to the memory location of a specified address in the DRAM 202 by the single write operation. However, when writing the test data into the DRAM 202, the address must be written into the DRAM 202 in advance without fail. This address is supplied from the test address input terminals 104 as the 12-bit address data. When inputting the row address of the address, an L level control signal is supplied from the test row address strobe input terminal 105 to a RAS (Row Address Strobe) negation terminal of the DRAM 202. On the other hand, when inputting a column, an L level control signal is supplied from the test column address strobe input terminal 106 to a CAS (Column Address Strobe) negation terminal of the DRAM 202. In the normal mode, in which neither the row nor column address is input, both the control signals from the test row address strobe input terminal 105 and test column address strobe input terminal 106 are H level (1). The address data transferred from the test address input terminals 104 is 12 bits. The row address consists of a combination [1, 0] of 12 bits of the address data, thereby providing 2¹² rows (4096 rows), whereas the column address consists of a combination [1, 0] of five bits out of 12-bit address data, providing 2⁵ column (32 columns).

(2) Next, the test data read operation from the DRAM 202 will be described. First, the control signal supplied to the test output enabling terminal 108 is switched to the L level (0), and the control signal supplied to the test write enabling terminal 107 is switched to the H level (1), so that the terminals DQ(127:0) of the DRAM 202 are placed in the output enabled state and data read enabled state. Thus, the DRAM 202 reads its 128-bit test data (the 16 sets of the same 8-bit test data) in a single read operation, and transfers the data to the multiplexer 203 and identity/nonidentity decision circuit 204 through the wide data bus 206.

The 128-bit test data (16 sets of the same 8-bit test data) transferred from the DRAM 202 is written into the multiplexer 203. Receiving the selection control signal sent from the test data output selection terminals 109 to its terminals SEL, which is fixed at “0000” for example, the multiplexer 203 selects one of the 16 sets of the same 8-bit test data, and outputs the selected data from the test data output terminals 101 of the chip. Subsequently, the 8-bit test data output is externally compared with a predetermined 8-bit expected value.

At the same time, the 128-bit test data (16 sets of the same 8-bit test data) output from the DRAM 202 is divided into 16 sets of the same 8-bit test data, which are transferred to the identity/nonidentity decision circuit 204 through the data lines 208. The identity/nonidentity decision circuit 204 makes an identity/nonidentity decision between the 16 sets of the same 8-bit test data, so that a tester (not shown) connected to the test identity/nonidentity decision result output terminal 110 can monitor the decision result. If the DRAM 202 is normal, all the 16 sets of the same 8-bit test data agree with each other, while if the DRAM 202 has some failure, they disagree. For, example, if the output result is “1”, it is decided that they agree, whereas if “0”, they disagree.

As described above, the conventional integrated circuit makes a decision that the DRAM 202 is normal when the 8-bit test data output from the test data output terminals 101 agrees with the predetermined 8-bit expected value, and when the decision result output from the test identity/nonidentity decision result output terminal 110 indicates the agreement, and that the DRAM 202 is abnormal if either the result output from the test data output terminals 101 or the decision result output from the test identity/nonidentity decision result output terminal 110 indicates disagreement.

With the foregoing configuration, although the conventional integrated circuit can make a simultaneous decision as to the 128 bits of the 128-bit wide data bus DRAM 202, it is necessary for the decision of the DRAM 202 to satisfy the two conditions that the 8-bit test data output from the test data output terminals 101 agrees with the 8-bit expected value, and that the decision result output from the test identity/nonidentity decision result output terminal 110 indicates agreement. In other words, the decision as to whether the DRAM 202 is normal or not must be made from the total of 9-bit decision results consisting of the 8-bits data output from the test data output terminals 101, and one bit data output from the test identity/nonidentity decision result output terminal 110. Therefore, the tester connected to the conventional integrated circuit 10 for analyzing the decision result must be assigned nine decision terminals for each chip. Since the total number of the decision terminals of the tester is physically limited, the number of chips that can be examined in a single test is limited, offering a problem of increasing the test time and hindering the reduction of the cost of the test.

### SUMMARY OF THE INVENTION

The present invention is implemented to solve the foregoing problem. It is therefore an object of the present invention to provide an integrated circuit capable of achieving the unit test of its memory simply and positively.

According to an aspect of the present invention, there is provided an integrated circuit comprising: test data write means for writing m×n-bit test data into a memory to be tested, in a single write operation by supplying same m-bit test data to each of n m-bit data buses that constitute an m×n-bit wide data bus connecting the test data write means to the memory to be tested; and decision means for receiving m×n-bit test data read out of the memory onto the wide data bus on an m-bit by m-bit basis in parallel, for comparing each m-bit test data with a same expected value of the m-bit test data every time the m-bit test data is supplied to the decision means, and for making a decision that the memory is normal only when all the m-bit test data supplied to the decision means agree with the expected value.

Here the integrated circuit may further comprise diagnostic means, activated when diagnosing the decision means, for transferring m×n bit diagnostic data different from the m×n bit test data to the wide data bus on every m-bit basis, for having the decision means compare the expected value with each m-bit diagnostic data supplied in parallel, and for having the decision means output a diagnostic result that the decision means has a fault if all the m-bit diagnostic data agree with the expected value.

The decision means may utilize the m×n-bit test data supplied from the memory through the wide data bus, without outputting the test data to outside.

The decision means may be connected to test data input terminals for supplying the test data write means with the m-bit test data, and capture the m-bit test data from the test data input terminals as the expected value.

### BRIEF DESCRIPTION OF THE DRAWINGS

FIG. 1 is a circuit diagram showing a configuration of a major portion of an embodiment 1 of an integrated circuit in accordance with the present invention;

FIG. 2 is a circuit diagram showing a configuration of a major portion of an embodiment 2 of the integrated circuit in accordance with the present invention;

FIG. 3 is a circuit diagram showing a configuration of a major portion of an embodiment 3 of the integrated circuit in accordance with the present invention;

FIG. 4 is a circuit diagram showing a configuration of a major portion of an embodiment 4 of the integrated circuit in accordance with the present invention; and

FIG. 5 is a circuit diagram showing a configuration of a major portion of a conventional integrated circuit.

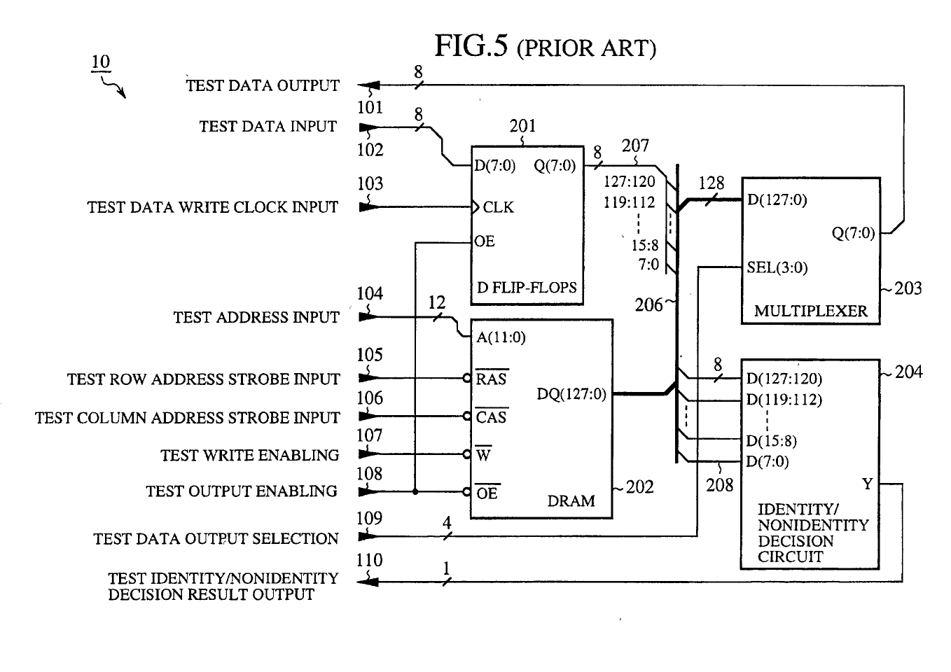

### DETAILED DESCRIPTION OF THE PREFERRED EMBODIMENTS

The invention will now be described with reference to the accompanying drawings.

Embodiment 1

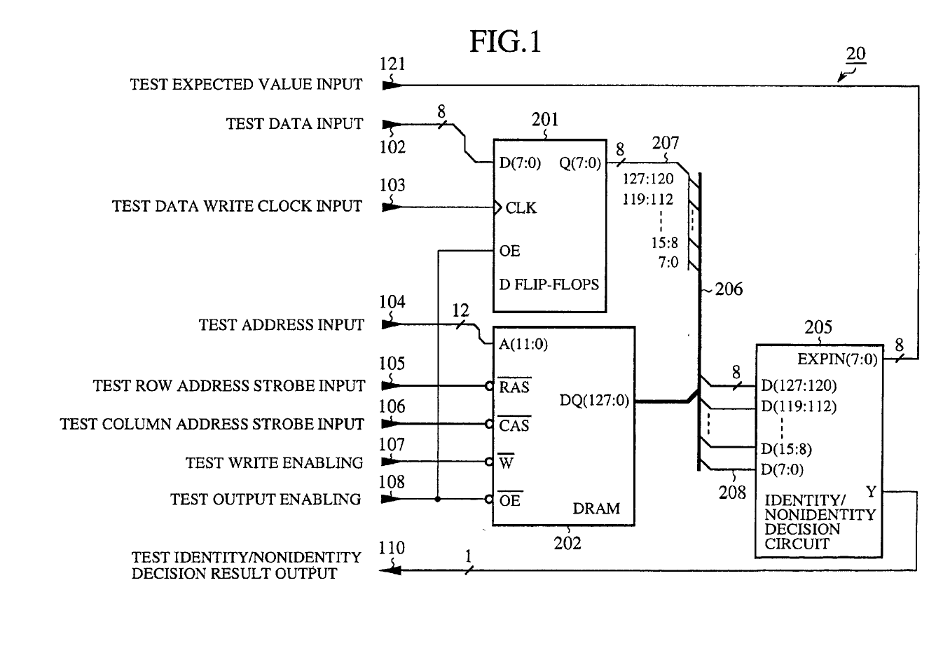

FIG. 1 is a circuit diagram showing a configuration of a major portion of an embodiment 1 of an integrated circuit in accordance with the present invention. In this figure, the reference numeral 20 designates an integrated circuit comprising a memory along with a wide data bus and its test circuit. The reference numeral 201 designates D flip-flops; 202 designates a 16M-bit DRAM (Dynamic Random Access Memory) as an object to be tested; and 205 designates an identity/nonidentity decision circuit for making a decision as to whether the DRAM 202 is normal or not. The D flip-flops 201 and the DRAM 202 have the same configurations as their conventional counterparts, and the terminals 102-108 and 110 are the same, and hence the description thereof is omitted here. The reference numeral 121 designates test expected value input terminals.

The wide data bus 206 connecting the D flip-flops 201 and the DRAM 202, and the m-bit data lines 207 connecting the D flip-flops 201 and the wide data bus 206 have the same structure as their conventional counterparts. The reference numeral 208 designates m-bit (=8-bit) data lines for connecting the wide data bus 206 and the identity/nonidentity decision circuit 205. The m-bit data lines 208 divide the 128-bit data from the wide data bus 206 to 16 sets of the same 8-bit test data, and supply them to the n (=16) terminals D(7:0)-D(127:120) of the identity/nonidentity decision circuit 205. Here, the D flip-flops 201, the data lines 207 and the wide data bus 206 constitute a test data write means for writing test data to the DRAM 202; and the wide data bus 206,-the data lines 208 and the identity/nonidentity decision circuit 205 constitute a decision means for making a decision as to whether the DRAM 202 is normal or not.

The identity/nonidentity decision circuit 205 comprises n terminals D(7:0)-D(127:120) for receiving the m×n-bit DQ output of the DRAM 202 by dividing them at every m-bit unit from the upper bits; terminals EXPIN (7:0) for receiving, as the expected value, the same data as the m-bit test data written into the D flip-flops 201; and a terminal Y for outputting a decision result. It compares the expected value with the DQ output of the DRAM 202 to make an identity/nonidentity decision. It decides that they agree only when each of the n sets of data at the n terminals D(7:0)-D(127:120) agrees with the data at the terminals EXPIN (7:0), and that they disagree otherwise. The decision result is supplied from the terminal Y to the test identity/nonidentity decision result output terminal 110.

Next, the operation of the present embodiment 1 will be described.

(1) First, the operation of the integrated circuit 20 when writing test data to the DRAM 202 will be described. The 8-bit test data supplied from the test data input terminals 102 is written into the D flip-flops 201 in response to the rising edge of the clock pulse fed from the test data write clock input terminal 103. The 8-bit test data is immediately output from the output terminals Q(7:0) of the D flip-flops 201.

The D flip-flops 201 and DRAM 202 both have an output control function so that when the control signal supplied to the test output enabling terminal 108 is at the H level (1), the output terminals Q(7:0) of the D flip-flops 201 are set at the output enabled state, whereas the output terminals DQ (127:0) of the DRAM 202 are set at the output disabled state because of the H level (1) supplied to its enabling terminal. In contrast, when the control signal input to the test output enabling terminal 108 is at the L level (0), the terminals Q(7:0) of the D flip-flops 201 are set at the output disabled state in which it cannot output the 8-bit test data, whereas the terminals DQ(127:0) of the DRAM 202 are set at the output enabled state because of the L level (0) control signal input to its enabling terminal. Thus, the D flip-flops 201 and the DRAM 202 can avoid the collision of the output data on the wide data bus 206 thanks to their output control functions. In the test data write operation, the control signal input to the test output enabling terminal 108 is placed at the H level (1).

The 8-bit test data output from the output terminals Q(7:0) of the D flip-flops 201 are distributed to the data lines 207 as 16 sets of the same 8-bit test data. Accordingly, the 16 sets of the same 8-bit test data, that is, 128-bit data, are written into the DRAM 202 through the 128-bit wide data bus 206 by a single write operation. The DRAM 202 receives the L level (0) control signal from the test write enabling terminal 107 in the write operation, whereas it receives the H level (1) control signal from the test write enabling terminal 107 in the read operation to undergo read/write control. Thus, when the DRAM 202 loads the 128-bit test data, it receives the L level (0) control signal from the test write enabling terminal 107 without exception.

Thus, the 128-bit test data is written to the memory location of a specified address in the DRAM 202 by the single write operation. However, before writing the test data into the DRAM 202, the address must be written into the DRAM 202 without fail. The address is supplied from the test address input terminals 104 as the 12-bit address data. When inputting the row address of the address, an L level control signal is supplied from the test row address strobe input terminal 105 to a RAS (Row Address Strobe) negation terminal of the DRAM 202. On the other hand, when inputting a column, an L level control signal is supplied from the test column address strobe input terminal 106 to a CAS (Column Address Strobe) negation terminal of the DRAM 202. In the normal mode, in which neither the row nor column address is input, both the control signals from the test row address strobe input terminal 105 and test column address strobe input terminal 106 are H level (1) so that the H (1) control signals are supplied to the RAS negation terminal and CAS negation terminal of the DRAM 202. The address data transferred from the test address input terminals 104 is 12 bits. The row address consists of a combination [1, 0] of the 12 bits of the address data, thereby providing 2¹² rows (4096 rows), whereas the column address consists of a combination [1, 0] of five bits out of the 12-bit address data, providing 2⁵ column (32 columns).

(2) Next, the operation of the integrated circuit 20 when reading the test data from the DRAM 202 will be described. First, the control signal supplied to the test output enabling terminal 108 is switched to the L level (0), and the control signal supplied to the test write enabling terminal 107 is switched to the H level (1), so that the terminals DQ(127:0) of the DRAM 202 are placed in the output enabled state and data read enabled state. Thus, the DRAM 202 reads its 128-bit test data (16 sets of the same 8-bit test data) in a single read operation, and transfers the data to the identity/nonidentity decision circuit 205 through the wide data bus 206.

The 128-bit test data (16 sets of the same 8-bit test data) transferred from the DQ terminals of the DRAM 202 to the identity/nonidentity decision circuit 205 is divided at every m (=8) bits from the upper bits to be supplied to the n (=16) terminals D(7:0)-D(127:120) in parallel. The terminals EXPIN (7:0) of the identity/nonidentity decision circuit 205 are supplied with the same data as the m-bit test data written into the D flip-flops 201 from the test expected value input terminals 121 as the expected value so that it compares the DQ output of the DRAM 202 with the expected value to make an identity/nonidentity decision.

More specifically, when the entire n sets of the data transferred to the n terminals D(7:0)-D(127:120) each agree with the expected value supplied to the terminals EXPIN (7:0), that is, when the following equations hold, the identity/nonidentity decision circuit 205 supplies the H level (1) from its terminal Y to the test identity/nonidentity decision result output terminal 110.

D(7:0)=EXPIN(7:0),

D(15:8)=EXPIN(7:0),

D(23:15)=EXPIN(7:0),

D(119:112)=EXPIN(7:0),

D(120:126)=EXPIN(7:0), and

D(127:120)=EXPIN(7:0)

On the other hand, when any one of the sixteen equations above does not hold, the identity/nonidentity decision circuit 205 supplies the L level (0) from its terminal Y to the test identity/nonidentity decision result output terminal 110.

As described above, according to the present embodiment 1 of the integrated circuit 20, the decision as to whether the DRAM 202 is normal or not can be made from the 1-bit decision result output from the identity/nonidentity decision circuit 205. As described before, in the conventional integrated circuit 10 which makes the decision from the multiple-bit identity decision results, it is necessary to assign, for each chip to be tested, a plurality of decision terminals to the tester connected to the integrated circuit 10 for analyzing the decision results. In contrast, it is unnecessary for the present embodiment 1 to connect the tester to multiple terminals, but to the only 1-bit terminal per chip. As a result, the tester, the total number of the decision terminals of which is physically limited, can carry out the test of the same number of chips as the total number of its decision terminals at the same time. Thus, the present embodiment 1 offers an advantage of being able to increase the test efficiency, and to reduce the test duration and cost.

Furthermore, the present embodiment 1 is configured such that the identity/nonidentity decision circuit 205 is supplied with the m×n-bit test data read from the DRAM 202 through the wide data bus 206, and utilizes the test data for making the decision without transferring the test data to the outside. Therefore, it is unnecessary for the m×n-bit test data, which is read from the DRAM 202 onto the wide data bus 206, to be transferred to the outside in part or in its entirety, to be compared with the expected value by a circuit other than the identity/nonidentity decision circuit 205. In other words, the decision as to whether the DRAM 202 is normal or not is made only by the identity/nonidentity decision circuit 205. As a result, it is sufficient for the tester to monitor the only 1-bit identity decision result output from the decision means, offering an advantage of being able to implement high efficiency, inexpensive test.

Embodiment 2

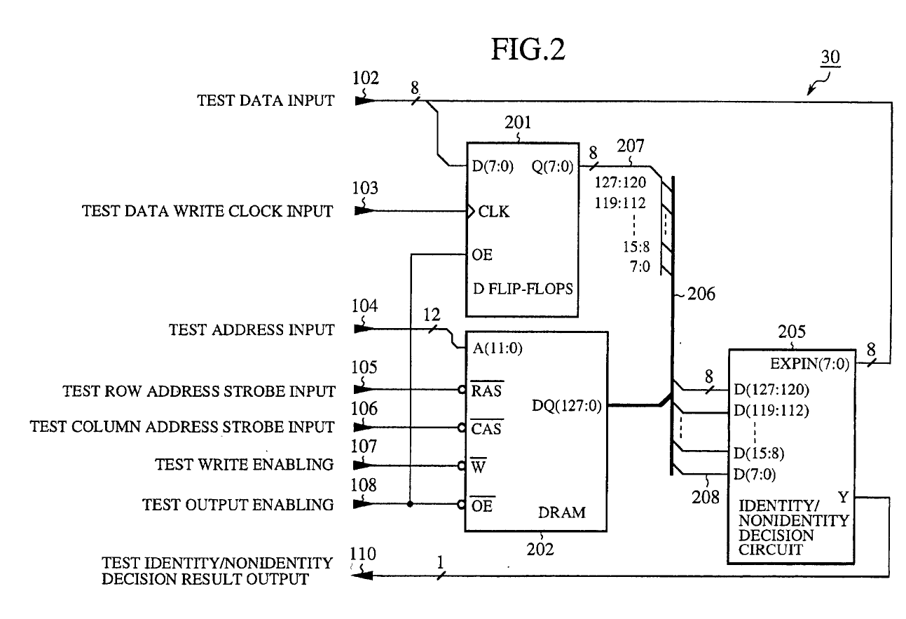

FIG. 2 is a circuit diagram showing a configuration of a major portion of an embodiment 2 of the integrated circuit in accordance with the present invention. Although the foregoing embodiment 1 of the integrated circuit 20 comprises the test expected value input terminals 121 and the test data input terminals 102 separately, the input terminals 121 and 102 can be made common. Thus, in the integrated circuit 30 as shown in FIG. 2, the test expected value input terminals 121 are omitted, and the test data input terminals 102, which share the function of the test expected value input terminals 121, are connected to the terminals EXPIN (7:0) of the identity/nonidentity decision circuit 205.

Next, the operation of the present embodiment 2 will be described.

First, when the test data is input to the D flip-flops 201, the test data is immediately transferred to the DRAM 202 to be written. During writing the data to the DRAM 202, it is designed such that the output of the identity/nonidentity decision circuit 205 through the test identity/nonidentity decision result output terminal 110 is not used by the tester to make the decision, and the m-bit test data supplied to the terminals EXPIN (7:0) is not used for the decision. Subsequently, when the DRAM 202 reads the test data, the identity/nonidentity decision circuit 205 starts operating to make the decision as to whether the contents of the DRAM 202 agree with the expected value by using the m-bit test data supplied from the test data input terminals 102 to the terminals EXPIN (7:0) as the expected value.

As described above, according to the present embodiment 2 of the integrated circuit 30, the test data input terminals 102 share the test expected value input terminals 121, thereby obviating the need for the test expected value input terminals 121 independently of the test data input terminals 102. This offers an advantage of being able to reduce the total number of input terminals of the circuit (by 8 bits in this example), and hence to make more effective use of the area for mounting the chip.

Embodiment 3

The foregoing embodiments 1 and 2 are configured such that the identity/nonidentity decision circuit 205 makes n times of identity/nonidentity decisions as to the m-bit test data to test whether the DRAM 202 is normal or not. However, if the identity/nonidentity decision circuit 205 has a fault (such as a stuck-at fault of its node), it is not unlikely that it makes an erroneous decision that the DRAM 202 is normal even though the DRAM 202 is actually abnormal. For example, when the entire bits of the m-bit data are “1”, but a particular bit is stored as “0” in the DRAM 202 because of its failure, and if the same particular bit is fixed at “1” because of the stuck-at fault of a node in the identity/nonidentity decision circuit 205, the identity/nonidentity decision circuit 205 makes a decision that the n sets of the same m-bit test data agree, and hence makes an erroneous decision that the DRAM 202 is normal in spite of its fault. In view of this, the present embodiment 3 is configured such that it detects the fault of the identity/nonidentity decision circuit 205 to prevent the erroneous decision due to the fault of the identity/nonidentity decision circuit 205.

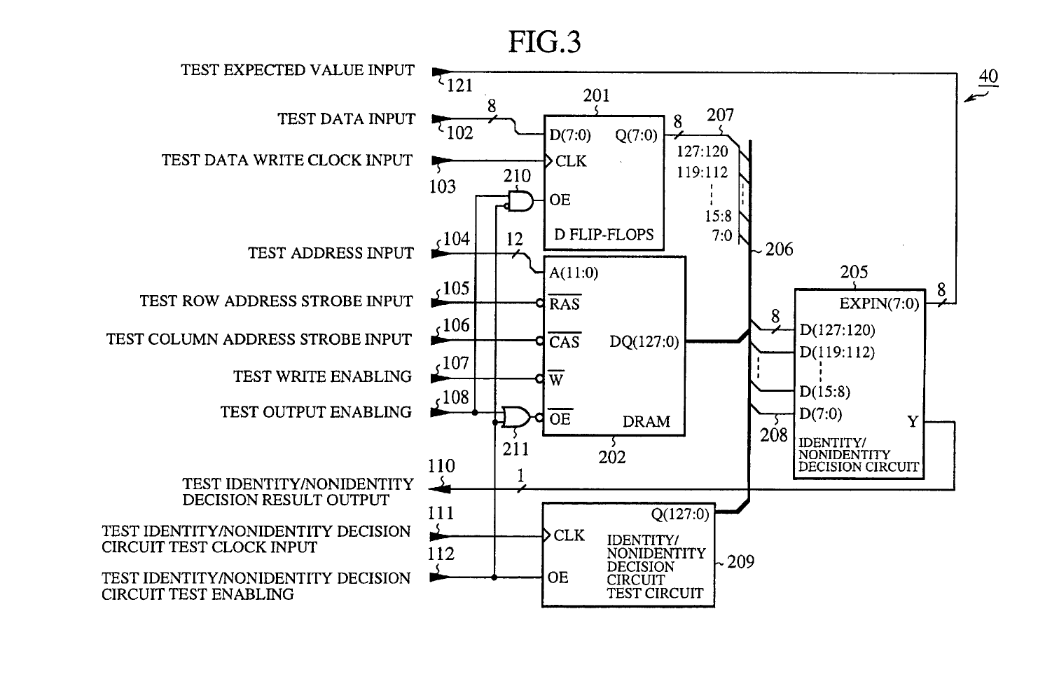

FIG. 3 is a circuit diagram showing a configuration of a major portion of an embodiment 3 of the integrated circuit in accordance with the present invention. In this figure, the reference numeral 40 designates an integrated circuit; and 209 designates an identity/nonidentity decision circuit test circuit (diagnostic means) for generating diagnostic data for detecting a fault in the identity/nonidentity decision circuit 205, and for transferring the diagnostic data to the identity/nonidentity decision circuit 205. The identity/nonidentity decision circuit test circuit 209 has an output control function for carrying out output control in response to a control signal supplied from an identity/nonidentity decision circuit test input terminal 112 to its terminal OE. The reference numeral 210 designates an AND circuit for ANDing the control signal from the test output enabling terminal 108 and an inverted signal of the control signal from the identity/nonidentity decision circuit test input terminal 112, and for supplying its output to the D flip-flops 201. The reference numeral 211 designates an OR circuit for ORing the control signal from the test output enabling terminal 108 and the control signal from the identity/nonidentity decision circuit test input terminal 112, and for supplying its output to the DRAM 202. In the present embodiment 3, the identity/nonidentity decision circuit test circuit 209, the wide data bus 206 and the data lines 208 constitute the diagnostic means for diagnosing the identity/nonidentity decision circuit 205. In FIG. 3, the same or like portions to those of FIG. 1 are designated by the same reference numerals, and the description thereof is omitted here.

Next, the operation of the present embodiment 3 will be described.

When testing as to whether the DRAM 202 is normal or not, the control signal fed from the identity/nonidentity decision circuit test input terminal 112 is at L level (0). Accordingly, the AND circuit 210 receives at its inverted input terminal the L level (0) control signal from the identity/nonidentity decision circuit test input terminal 112. Thus, the AND circuit 210 changes its output in response to the control signal from the test output enabling terminal 108 (specifically, its output becomes H level when the control signal is H level, and L level when the control signal is L level) Likewise, receiving the control signal of the low level (0) from the identity/nonidentity decision circuit test input terminal 112, the OR circuit 211 also changes its output in response to the control signal from the test output enabling terminal 108 (specifically, its output becomes H level when the control signal is H level, and L level when the control signal is L level). In this case, the identity/nonidentity decision circuit test circuit 209 is supplied with the L level (0) control signal from the identity/nonidentity decision circuit test input terminal 112, thereby being controlled such that its output from the terminals Q(127:0) is suppressed. In this condition, the unit test of the DRAM 202 is carried out in the same manner as in the foregoing embodiment 1.

When diagnosing the identity/nonidentity decision circuit 205, the control signal supplied from the identity/nonidentity decision circuit test input terminal 1-12 is placed at H level (1). Thus, the AND circuit 210 receives at its inverted input terminal the H level (1) control signal so that the AND circuit 210 always outputs the L level (0), thereby suppressing the output from the terminals Q(7, 0) of the D flip-flops 201. Likewise, the OR circuit 211 receives the H level (1) control signal so that its output is fixed at the H level (1), thereby suppressing the output from the terminals DQ(127:0) of the DRAM 202. On the other hand, the terminals Q(127:0) of the identity/nonidentity decision circuit test circuit 209 are enabled so that the diagnostic data (test pattern data) is transferred to the identity/nonidentity decision circuit 205 via the wide data bus 206. In the course of this, the D flip-flops 201, the DRAM 202 and the identity/nonidentity decision circuit test circuit 209 undergo the selective output control to avoid the data collision on the wide data bus 206.

The diagnostic data generated by the identity/nonidentity decision circuit test circuit 209 is transferred from the terminals Q(127:0) of the identity/nonidentity decision circuit test circuit 209 to the identity/nonidentity decision circuit 205 through the wide data bus 206. As the diagnostic data is used such a test pattern as including only one H level bit with the remaining 127 bits being L level and sequentially shifting the H level bit; or inversely, a test pattern as including only one L level bit with the remaining 127 bits being H level and sequentially shifting the L level bit. Such diagnostic data is supplied to the terminals D(127:120)-D(7:0) of the identity/nonidentity decision circuit 205. When the identity/nonidentity decision circuit 205 is normal, the decision result output from the test identity/nonidentity decision result output terminal 110 always indicates disagreement (“0”, for example). In contrast, if the identity/nonidentity decision circuit 205 includes a stuck-at fault or the like, the decision result output from the test identity/nonidentity decision result output terminal 110 can indicate agreement (“1”, for example). Accordingly, it is possible to detect the stuck-at fault or the like according to the H level or L level output of the identity/nonidentity decision circuit 205.

As described above, the present embodiment 3 of the integrated circuit 40 is configured such that it comprises the identity/nonidentity decision circuit test circuit 209 which supplies, when diagnosing the identity/nonidentity decision circuit 205, the wide data bus 206 with the m×n bit diagnostic data different from the m×n bit test data on an m-bit by m-bit basis, and that the identity/nonidentity decision circuit 205 compares each m-bit diagnostic data with the expected value, and if all of them agree with the expected value, it outputs the diagnostic result indicating that the identity/nonidentity decision circuit 205 includes a failure. Accordingly, when the identity/nonidentity decision circuit 205 has a fault like the stuck-at fault of a node, it can detect the fault using the diagnostic data generated by the identity/nonidentity decision circuit test circuit 209. This offers an advantage of being able to prevent the erroneous decision that the DRAM 202 is normal when it is actually abnormal, and to improve the decision quality.

Embodiment 4

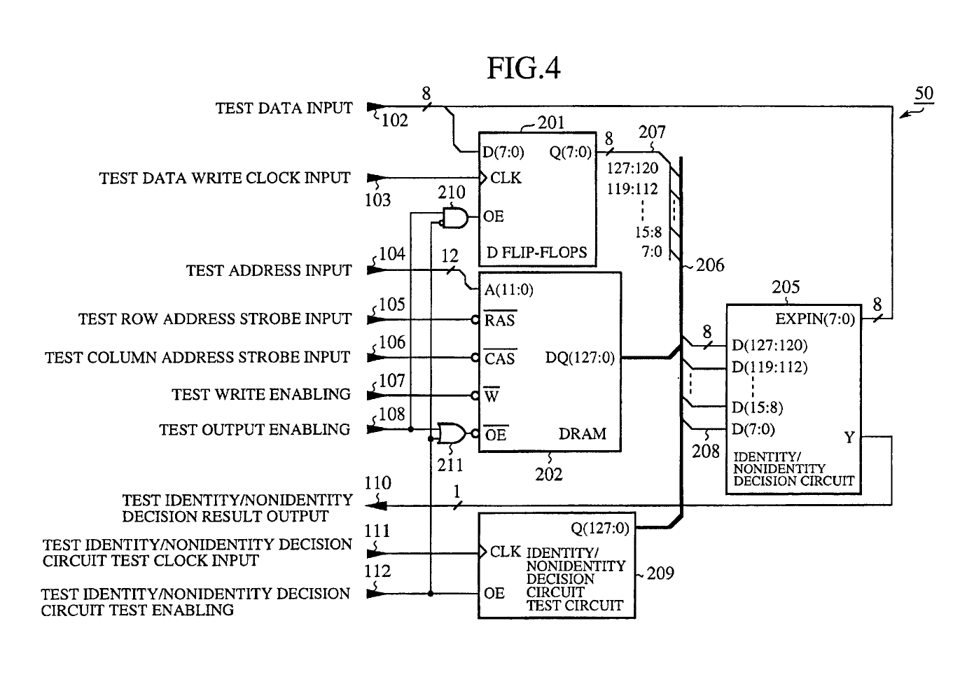

FIG. 4 is a circuit diagram showing a configuration of a major portion of an embodiment 4 of the integrated circuit in accordance with the present invention. Although the foregoing embodiment 3 of the integrated circuit 40 comprises the test expected value input terminals 121 and the test data input terminals 102 separately, the input terminals 121 and 102 can be made common. Thus, in the integrated circuit 40 as shown in FIG. 4, the test expected value input terminals 121 are omitted, and the test data input terminals 102 that share the function of the test expected value input terminals 121 are connected to the terminals EXPIN (7:0) of the identity/nonidentity decision circuit 205.

Next, the operation of the present embodiment 4 will be described.

First, when the test data is input to the D flip-flops 201, the test data is immediately transferred to the DRAM 202 to be written. During writing the data to the DRAM 202, it is designed such that the output of the identity/nonidentity decision circuit 205 through the test identity/nonidentity decision result output terminal 110 is not used by the tester to make the decision, and the m-bit test data supplied to the terminals EXPIN (7:0) is not used for the decision. Subsequently, when the DRAM 202 reads the test data, the identity/nonidentity decision circuit 205 starts its operation to make the decision as to whether the content of the DRAM 202 agree with the expected value by using the m-bit test data supplied from the test data input terminals 102 to the terminals EXPIN (7:0) as the expected value.

As described above, according to the present embodiment 4 of the integrated circuit 50, the test data input terminals 102, which share the function of the test expected value input terminals 121, obviates the need for providing the test expected value input terminals 121 independently of the test data input terminals 102. This offers an advantage of being able to reduce the total number of input terminals of the circuit (by 8 bits in this example), and hence to make more effective use of the area for mounting the chip.

Although the foregoing embodiments 1-4 of the integrated circuit 20-50 are described taking an example using the DRAM 202 as their memory, the memory is not limited to the DRAM. For example, a synchronous DRAM or SRAM can be used instead.

What is claimed is:

1. An integrated circuit comprising:
test data write means for writing m×n-bit test data into a memory to be tested, in a single write operation by supplying same m-bit test data to each of n m-bit data buses that constitute an m×n-bit wide data bus connecting said test data write means to the memory to be tested; and
decision means for receiving m×n-bit test data read out of the memory onto the wide data bus on an m-bit by m-bit basis in parallel, for comparing each m-bit test data with a same expected value of the m-bit test data every time the m-bit test data is supplied to said decision means, and for making a decision that the memory is normal only when all the m-bit test data supplied to the decision means agree with the expected value.

2. The integrated circuit according to claim 1, wherein said decision means utilizes the m×n-bit test data supplied from the memory through the wide data bus, without outputting the test data to outside.

3. The integrated circuit according to claim 1, wherein said decision means is connected to test data input terminals for supplying said test data write means with the m-bit test data, and captures the m-bit test data from the test data input terminals as the expected value.

4. The integrated circuit according to claim 2, wherein said decision means is connected to test data input terminals for supplying said test data write means with the m-bit test data, and captures the m-bit test data from the test data input terminals as the expected value.

5. The integrated circuit according to claim 1, further comprising diagnostic means, activated when diagnosing said decision means, for transferring m×n bit diagnostic data different from the m×n bit test data to the wide data bus on every m-bit basis, for having said decision means compare the expected value with each m-bit diagnostic data supplied in parallel, and for having said decision means output a diagnostic result that said decision means has a fault if all the m-bit diagnostic data agree with the expected value.

6. The integrated circuit according to claim 5, wherein said decision means utilizes the m×n-bit test data supplied from the memory through the wide data bus, without outputting the test data to outside.

7. The integrated circuit according to claim 5, wherein said decision means is connected to test data input terminals for supplying said test data write means with the m-bit test data, and captures the m-bit test data from the test data input terminals as the expected value.

8. The integrated circuit according to claim 6, wherein said decision means is connected to test data input terminals for supplying said test data write means with the m-bit test data, and captures the m-bit test data from the test data input terminals as the expected value.
